(19) United States
(12) Patent Application Publication
(10) Pub. No.: US 2009/0169718 A1
(43) Pub. Date: Jul. 2, 2009

(54) UNIT AND METHOD FOR PREPARING AN OPENING DEVICE FOR GLUING TO A RESPECTIVE SEALED PACKAGE OF A POURABLE FOOD PRODUCT

(75) Inventors: Paolo Casarini, Prato di Correggio (IT); Antonio Tarroni, Formigine (IT); Roberto Nicolini, Spilamberto (IT)

Correspondence Address: BUCHANAN, INGERSOLL & ROONEY PC, POST OFFICE BOX 1404, ALEXANDRIA, VA, 22313-1404, US

(73) Assignee: Tetra Laval Holdings & Finance SA, Pully (CH)

(21) Appl. No.: 12/297,001

(22) PCT Filed: Apr. 20, 2007
(86) PCT No.: PCT/EP07/53917

§ 371 Date: Oct. 13, 2008

(30) Foreign Application Priority Data
Apr. 21, 2006 (IT) TO2006A000298

(51) Int. Cl. C23C 16/52; B05C 11/00

(52) U.S. Cl. 427/8; 118/668

(57) ABSTRACT

A unit for preparing an opening device for gluing to a respective sealed package of a pourable food product includes a conveyor for feeding the opening device along a predetermined path, a dispenser for depositing a layer of adhesive onto a portion of the opening device to be applied to a corresponding package; and a monitor for identifying, on the opening device, the position of the layer of adhesive with respect to the adhesive-receiving portion, and which generate a signal associated with the shape of the identified layer.

### TECHNICAL FIELD

The present invention relates to a unit and method for preparing an opening device for gluing to a respective sealed package of a pourable food product.

### BACKGROUND ART

As is known, many pourable food products, such as fruit juice, UHT (ultra-high-temperature treated) milk, wine, tomato sauce, etc., are sold in packages made of sterilized packaging material.

A typical example of this type of package is the parallelepiped-shaped package for liquid or pourable food products known as Tetra Brik Aseptic (registered trademark), which is made by folding and sealing laminated strip packaging material. The packaging material has a multilayer structure comprising a base layer for stiffness and strength, which may comprise a layer of fibrous material, e.g. paper, or of mineral-filled polypropylene material, and which is covered on both sides with layers of thermoplastic material, e.g. polyethylene film. In the case of aseptic packages for long-storage products, such as UHT milk, the packaging material comprises a layer of oxygen-barrier material, e.g. aluminium foil, which is superimposed on a layer of thermoplastic material, and is in turn covered with another layer of thermoplastic material forming the inner face of the package eventually contacting the food product.

Packages of this sort are produced on fully automatic packaging machines, on which a continuous tube is formed from the web-fed packaging material; the web of packaging material is sterilized on the packaging machine, e.g. by applying a chemical sterilizing agent, such as a hydrogen peroxide solution, which, once sterilization is completed, is removed from the surfaces of the packaging material, e.g. evaporated by heating; and the web of packaging material so sterilized is maintained in a closed, sterile environment, and is folded and sealed longitudinally to form a vertical tube.

The tube is filled with the sterilized or sterile-processed food product, and is sealed and subsequently cut along equally spaced cross sections to form pillow packs, which are then folded mechanically to form respective finished, e.g. substantially parallelepiped-shaped, packages.

Alternatively, the packaging material may be cut into blanks, which are formed into packages on forming spindles, and the packages are filled with the food product and sealed. One example of this type of package is the so-called “gable-top” package known by the trade name Tetra Rex (registered trademark).

Once formed, the above packages may undergo further processing, such as the application of a reclosable opening device to protect the food product inside the package from contact with external agents, and to enable the product to be poured out.

At present, the most commonly marketed opening devices comprise an annular frame portion defining a pour opening and fitted about a removable or pierceable portion of a top wall of the package; and a cap hinged or screwed to the frame portion, and which is removable to open the package. Alternatively, other types of opening, e.g. slide-open, devices are also known to be used.

The opening devices are conveyed to a gluing unit for depositing a layer of adhesive, usually high-temperature liquid glue, onto each opening device.

More specifically, the adhesive performs the dual function of fixing each opening device permanently to the respective package, and of sealing the frame portion of each opening device to the top wall of the package.

For both these functions to be performed correctly, an uninterrupted annular adhesive layer, having a transverse dimension over a predetermined threshold value, must be deposited on each opening device.

Known gluing units do not permit automatic control of the shape of the adhesive layer.

This is normally done visually by the operator, and is therefore unrepeatable and poses difficulties on account of the similar, and hence easily mistakable, chromatic properties of the adhesive and the opening device.

Failure to deposit the adhesive as described above may therefore result, when using the package, in detachment of the opening device from the package, or leakage of the food product between the frame portion of the opening device and the top wall of the package.

### DISCLOSURE OF INVENTION

It is an object of the present invention to provide a unit for preparing an opening device for gluing to a respective sealed package of a pourable food product, designed to eliminate the aforementioned drawback typically associated with known application units.

According to the present invention, there is provided a unit for preparing an opening device for gluing to a respective sealed package of a pourable food product, as claimed in Claim 1.

The present invention also relates to a method of preparing an opening device for gluing to a respective package of a pourable food product, as claimed in Claim 12.

### BRIEF DESCRIPTION OF THE DRAWINGS

Two preferred, non-limiting embodiments of the present invention will be described by way of example with reference to the accompanying drawings, in which:

FIG. 1 shows a view in perspective of a unit, in accordance with the invention, for preparing an opening device for gluing to a respective sealed package of a pourable food product and for applying such opening device to the package;

FIG. 2 shows a larger-scale front view of a central core of the FIG. 1 unit;

FIG. 3 shows a larger-scale first view in perspective of a gripping member of the FIGS. 1 and 2 unit for feeding a respective opening device from a pickup area to an area of application to a respective package;

FIG. 4 shows a second view in perspective of the FIG. 3 gripping member;

FIG. 5 shows a smaller-scale view in perspective of an actuating mechanism for operating the FIGS. 3 and 4 gripping member;

FIG. 6 shows a side view, with parts removed for clarity, of a portion of the FIGS. 1 and 2 unit;

FIG. 7 shows the image of an opening device with a correctly deposited annular layer of adhesive as captured by an image acquisition device of the FIGS. 1 and 2 unit;

FIG. 8 shows a view in perspective of an alternative embodiment, in accordance with the present invention, of the FIG. 1 unit;

FIG. 9 shows an annular layer of adhesive deposited correctly by the FIG. 8 unit onto a respective opening device;

FIG. 10 shows the radial thickness pattern of the FIG. 9 layer as a function of an angular coordinate measured along the layer;

FIG. 11 shows an annular layer of adhesive deposited incorrectly by the FIG. 8 unit onto a respective opening device; and

FIG. 12 shows the radial thickness pattern of the FIG. 11 layer as a function of an angular coordinate measured along the layer.

### BEST MODE FOR CARRYING OUT THE INVENTION

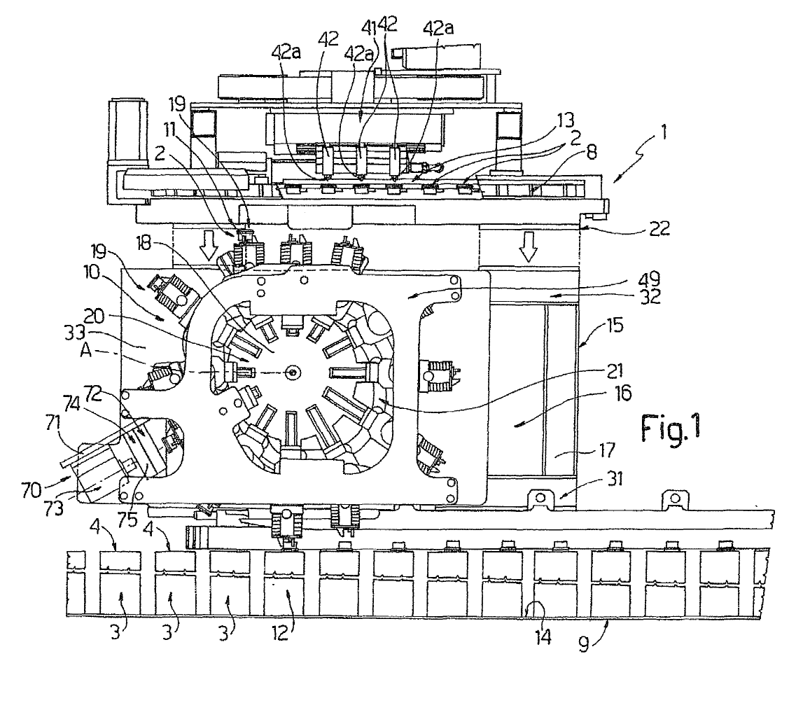

Number 1 in FIG. 1 indicates as a whole a unit, in accordance with the present invention, which can be incorporated in a known pourable food product packaging machine (not shown) of the type described in the introduction.

Unit 1 provides for preparing a succession of reclosable plastic opening devices 2 for gluing to respective packages 3 filled, sealed and formed on the machine. Unit 1 further provides for applying opening devices 2 to respective packages 3.

As it is known, packages 3 are produced from sheet packaging material comprising a base layer, e.g. of fibrous material such as cardboard, or of mineral-filled polypropylene material; and a number of layers of heat-seal plastic material, e.g. polyethylene film, covering both sides of the base layer. In the case of aseptic packages 3 for long-storage products, such as UHT milk, the packaging material also comprises a layer of gas- and light-barrier material, e.g. aluminum foil or ethyl vinyl alcohol (EVOH) film, which is superimposed on a layer of heat-seal plastic material, and is in turn covered with another layer of heat-seal plastic material forming the inner face of package 3 eventually contacting the food product.

Each package 3, which is substantially parallelepiped-shaped in the example shown, has, on an end wall 4, an opening or a pierceable or removable portion (not shown), which is covered outwardly by a respective opening device 2 applied to package 3 by relative unit 1.

The pierceable or removable portion may be defined by a sealing sheet glued or heat-sealed to the package to close a through hole in the packaging material, or may be defined by a so-called “prelaminated” hole, i.e. a hole formed in the base layer of the packaging material and sealed hermetically by other layers of the packaging material (at least the thermoplastic layers).

More specifically, opening devices 2 in FIGS. 1, 2, 3, 4, 6 and 7 are screw types made of plastic material, and each comprise in known manner an annular, externally threaded frame 5, which is fixed to wall 4 of a respective package 3 and defines a through opening 6 by which to pour out the food product; and an internally threaded cap 7 screwed to frame 5 to close opening 6. Opening devices 2 may also comprise, in known manner, means (not shown) for piercing the pierceable portion or removing the removable portion of package 3 when unsealing the package. As an example, the cap 7 may be internally provided with a portion (not shown) extending through opening 6 of frame 5 and which may be directly glued to the removable portion; when package 3 is unsealed by screwing off cap 7, the removable portion remains attached to cap 7 and is removed together with it.

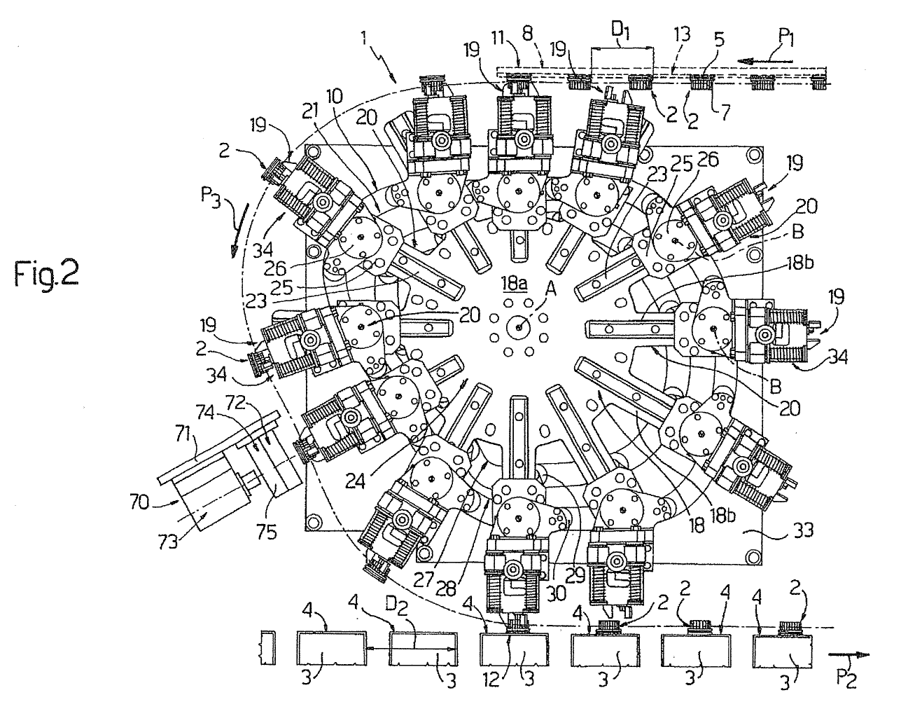

With reference to FIGS. 1 and 2, unit 1 substantially comprises a supporting structure 15; a first linear conveyor 8, known and only shown schematically, for feeding a succession of opening devices 2 along a straight horizontal path P₁; a second linear conveyor 9, also known and only shown schematically, for feeding a succession of packages 3 along a straight horizontal path P₂ parallel and in the opposite direction to path P₁ in the example shown; and a transfer conveyor wheel 10 for feeding opening devices 2 from a pickup station 11 located along path P₁, to an application station 12 located along path P₂ and for applying opening devices 2 to respective packages 3.

Supporting structure 15 comprises a substantially parallelepiped-shaped central body 16 defined by a number of parallel uprights 17 (only one shown in FIG. 1) to which are fixed respectively a bottom beam system 31 and a top beam system 32.

Conveyor 8 is mounted on a supporting beam system 22 in turn fixed to top beam system 32 of central body 16, and defines, at least close to pickup station 11, a horizontal conveying surface 13, on which opening devices 2 are positioned with caps 7 downwards facing conveyor wheel 10.

Supporting beam system 22 is also fitted on top with an adhesive dispensing device 41—in the example shown, for hot-melt glue—which acts on opening devices 2 as they travel along conveyor 8. More specifically, dispensing device 41 comprises a number of—in the example shown, three—dispensing guns 42 aligned parallel to path P₁, and each having a respective nozzle 42a facing conveying surface 13 to feed a layer 45 of adhesive (FIG. 7) onto a respective opening device 2. As they travel along path P₁, opening devices 2 are coated with layer 45 of adhesive on the upward-facing side, i.e. the side opposite that facing conveyor wheel 10.

More specifically, each dispensing gun 42 travels along a predetermined path to distribute layer 45 of adhesive onto the respective opening device 2. In the example shown in FIGS. 1 to 7, layer 45 of adhesive is distributed annularly onto the surface of frame 5 which is designed to be attached around the removable portion of package 3.

As a possible alternative not shown, when cap 7 is provided with an internal portion designed to be directly attached to the removable portion of package 3, the layer of adhesive may be also distributed on that portion of the cap.

Conveyor 9 is located below conveyor 8 and central body 16 of supporting structure 15, and defines, at least close to application station 12, a horizontal conveying surface 14, on which packages 3 stand with respective walls 4, to which opening devices 2 are eventually applied, positioned horizontally on top, facing conveyor wheel 10.

In the example shown, the spacing D₁ of opening devices 2 along conveyor 8 is different from, and more specifically smaller than, the spacing of D₂ of packages 3 along conveyor 9; the term “spacing” being used in the sense of the distance between corresponding points of two adjacent opening devices 2 or two adjacent packages 3.

By means of a respective supporting beam system 49, conveyor wheel 10 is fixed to and projects from the front of central body 16 of supporting structure 15, and is therefore interposed between conveyors 8 and 9.

Conveyor wheel 10 rotates continuously about a horizontal axis A perpendicular to paths P₁ and P₂, and feeds opening devices 2 along a curved path P₃ from pickup station 11 to application station 12.

With particular reference to FIG. 2, conveyor wheel 10 comprises a wheel 18 of axis A; and a number of gripping members 19 equally spaced about axis A and fitted to and projecting radially from wheel 18.

Unit 1 also comprises a number of connecting assemblies 20 for connecting respective gripping members 19 movably to wheel 18; and cam guide means 21 for altering the position of each gripping member 19 with respect to wheel 18 as wheel 18 rotates. The spacing of opening devices 2 along path P₃ can thus be adjusted as required to adapt it to the requirements of specific operations to be performed on opening devices 2, and to make it equal to spacing D₂ of packages 3 at application station 12.

With reference to FIGS. 2, 3, 4 and 6, connecting assemblies 20 comprise a number of guide members 23 extending radially about axis A and fixed to and projecting from an end surface 24 of wheel 18; and a number of slide members 25 fitted in sliding manner to respective guide members 23, and each supporting a respective gripping member 19.

More specifically, wheel 18 has a central disk-shaped portion 18a, from which project peripherally a number of radial projections 18b, each fitted with a respective guide member 23.

Each gripping member 19 is fitted to a plate 26, which is hinged to respective slide member 25, on the opposite side to respective guide member 23, and about a respective axis B parallel to axis A and perpendicular to plate 26.

Each gripping member 19 can therefore translate with respect to wheel 18 in a given radial direction with respect to axis A, and can oscillate with respect to wheel 18 about a respective axis B perpendicular to and incident with said radial direction.

As shown in FIG. 2, guide means 21 comprise two curved fixed cams 27, 28 extending seamlessly about axis A and cooperating with respective idle cam follower rollers 29, 30 fitted to slide member 25 and plate 26, respectively, of connecting assembly 20 of each gripping member 19.

More specifically, cams 27, 28 are defined by respective contoured grooves formed in a fixed vertical wall 33 located behind wheel 18 with reference to FIGS. 1 and 2, or, more specifically, positioned facing an end surface of wheel 18 opposite end surface 24. All parts of cam 28 are located radially outwards of cam 27.

Cam 27 controls the radial position of gripping members 19 with respect to axis A as wheel 18 rotates, while cam 28 controls the orientation of gripping members 19, and therefore of opening devices 2, with respect to the radius of wheel 18 to which they are fixed.

As shown in FIG. 2, gripping members 19, and therefore opening devices 2, change position with respect to wheel 18 as wheel 18 rotates, thus altering their peripheral speed. Which change in position between pickup station 11 and application station 12 provides for adapting the spacing of opening devices 2 to that (D₂) of packages 3.

With reference to FIGS. 2, 3, 4 and 6, each gripping member 19 is fixed to respective plate 26 by a supporting frame 34 projecting from plate 26 on the opposite side to respective slide member 25.

More specifically, each frame 34 comprises a main body 35 which is substantially L-shaped in a plane perpendicular to respective plate 26, and is defined by a first plate portion 36 fixed parallel to and against plate 26, and by a second plate portion 37 projecting perpendicularly from plate portion 36, on the opposite side to respective slide member 25. Each frame 34 also comprises two pins 38 extending from a free end of relative plate portion 37 in a direction parallel to and facing relative plate portion 36; and a fastening body 39 which is fitted integrally with relative gripping member 19, is fitted in sliding manner to pins 38, and is loaded elastically, by helical springs 40 coaxial with respective pins 38, into a first withdrawn operating position, i.e. at a minimum radial distance from axis A with reference to the specific radial position occupied by relative slide member 25 along relative guide member 23.

More specifically, fastening body 39 of each frame 34 comprises a main plate portion 43 extending parallel to relative plate 26 and to plate portion 36 of relative main body 35, and from which relative gripping member 19 projects on the opposite side to that adjacent to relative plate portion 37; and an appendix 44 which extends perpendicularly from the end of main portion 43 adjacent to plate portion 37, and defines two through holes engaged in sliding manner by respective pins 38.

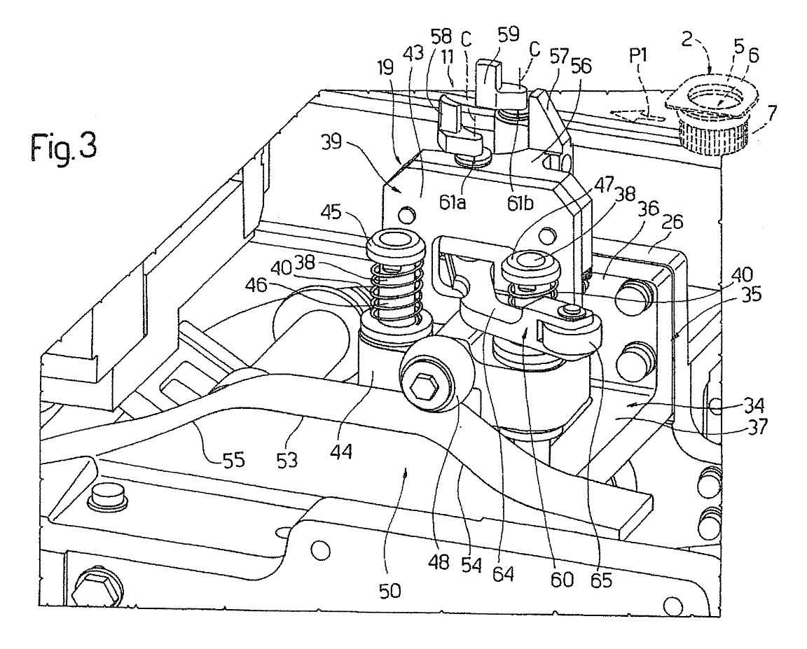

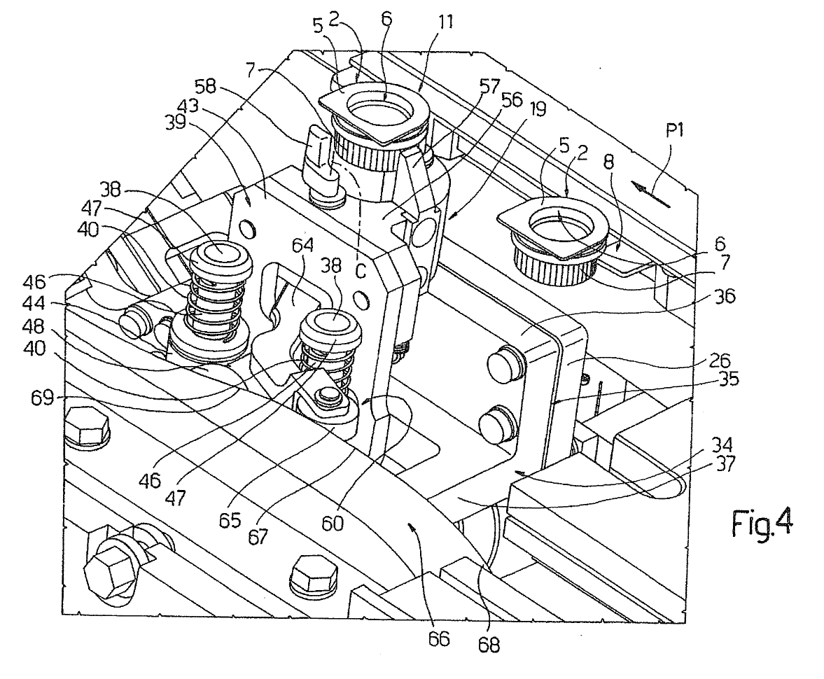

As shown in FIGS. 3 and 4, pins 38 of each frame 34 extend through relative appendix 44, and have respective portions 46 projecting from appendix 44 and facing relative main portion 43. Each portion 46 is wound externally with a respective spring 40 interposed between relative appendix 44 and an annular end shoulder 47 of portion 46.

A cam follower roller 48 is fitted to and projects from appendix 44 of each frame 34, on the opposite side to relative main portion 43, and cooperates in rolling manner with two fixed cams 50 (shown in FIGS. 3 and 6) located respectively at stations 11 and 12.

With reference to FIGS. 3 and 6, cams 50 are located on the opposite side of wheel 18 to vertical wall 33 supporting cams 28, 29, and each comprise a top portion 53 projecting radially outwards with respect to axis A, and from which extend respective oppositely-inclined ramp portions 54, 55. With reference to the rotation direction of wheel 18, ramp portion 54 of each cam 50 slopes upwards towards relative top portion 53, and ramp portion 55 slopes downwards from top portion 53. As each cam follower roller 48 rolls along each cam 50, relative gripping member 19 is first moved from the first withdrawn operating position to a second forward operating position, reached at top portion 53 of cam 50, and then returns to its original position.

In the second forward operating position, each gripping member 19 is located a maximum radial distance from axis A with reference to the radial position occupied by relative slide member 25 along relative guide member 23. Pickup and release of opening devices 2 by gripping members 19 are performed respectively in said second operating position.

With particular reference to FIGS. 3 and 4, each gripping member 19 comprises a supporting body 56 fixed to and projecting from the end of main portion 43 of relative fastening body 39 opposite the end from which relative appendix 44 extends; and three jaws 57, 58, 59 projecting from the radially outermost side of supporting body 56 with respect to axis A, and for gripping a relative opening device 2. One of the jaws (57) is fixed to supporting body 56, while the other two (58, 59) oscillate about respective axes C perpendicular to axis A and to plate portion 37 of relative frame 34.

As shown in FIG. 4, when gripping relative opening device 2, jaws 57, 58, 59 of each gripping member 19 are equally spaced angularly about opening device 2.

More specifically, jaws 58, 59 of each gripping member 19 are loaded elastically into a closed position retaining relative opening device 2 between them and against fixed jaw 57, and are movable selectively, at stations 11 and 12, into an open position in which they are parted to permit engagement and release of opening device 2.

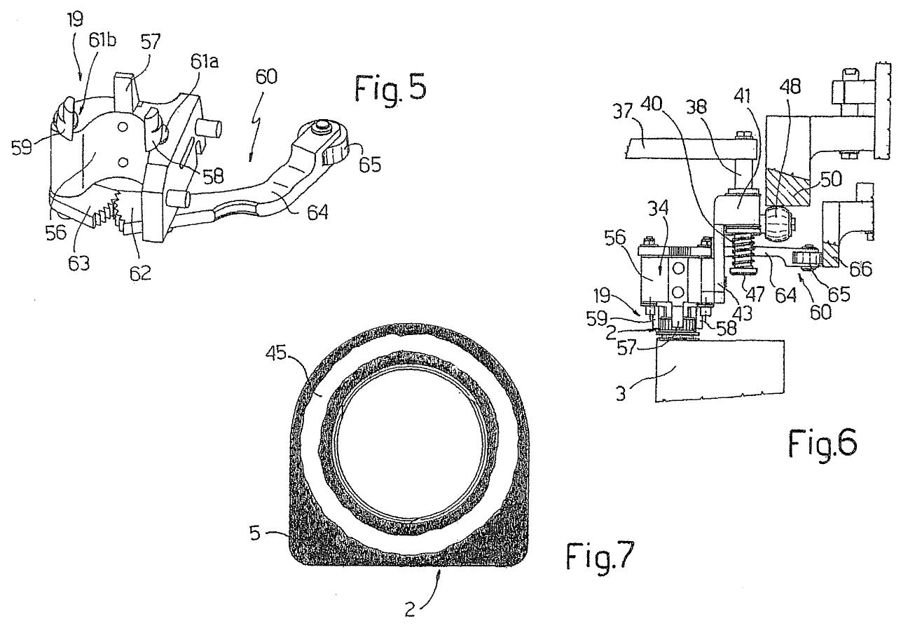

The movements of jaws 58, 59 of each gripping member 19 are controlled by a lever-and-cam actuating mechanism 60 shown in detail in FIGS. 4 and 5.

Actuating mechanism 60 comprises two pins 61a, 61b fitted in axially fixed and rotary manner through respective through holes in supporting body 56 of relative gripping member 19, and the opposite ends of which, projecting from supporting body 56, are fitted respectively with respective jaws 58, 59 and respective sector gears 62, 63 meshing with each other. One of the sector gears (62) defines an end portion of a respective lever 64, the other end portion of which is fitted with an idle cam follower roller 65 which cooperates in rolling manner with two fixed cams 66 (shown in FIGS. 4 and 6) located respectively at stations 11 and 12.

Cams 66 are located on the opposite side of wheel 18 to vertical wall 33 supporting cams 28, 29, and each comprise a top portion 67 projecting towards wheel 18 and from which extend respective oppositely-inclined ramp portions 68, 69. With reference to the rotation direction of wheel 18, ramp portion 68 of each cam 66 slopes upwards towards relative top portion 67, and ramp portion 69 slopes downwards from top portion 67.

As each cam follower roller 65 rolls along each cam 66, relative lever 64 is first rotated about the axis of relative pin 61a, thus moving jaws 58, 59 simultaneously into the open position, reached at top portion 67, and then rotates in the opposite direction to restore jaws 58, 59 to the closed position.

With reference to FIGS. 1 and 2, unit 1 advantageously comprises a monitoring apparatus 70 for identifying, on each opening device 2, the position of layer 45 of adhesive with respect to the portion (5) on which the adhesive is deposited, and which generates a signal associated with the shape of layer 45.

Monitoring apparatus 70 is preferably fixed to a wall 71 projecting from vertical wall 33 of supporting structure 15, alongside conveyor wheel 10 and upstream from application station 12. As clearly shown in FIGS. 1 and 2, monitoring apparatus 70 is installed along path P₃ and extends on one side of wall 71.

In particular, monitoring apparatus 70 comprises a radiating source 72, which is selectively activated for irradiating a given area of path P₃ traveled across by each opening device 2, and which emits electromagnetic radiations having given wavelengths at least in part in the ultraviolet region; an image acquisition device 73—in the example shown, a television camera—for capturing the image of the irradiated area and generating the above-mentioned signal associated with the detected image of layer 45 of adhesive; and a treatment device 74 for creating sufficient contrast in the captured image between layer 45 of adhesive and the portion of opening device 2 where such layer is deposited.

In the example shown in FIGS. 1 and 2, radiating source 72 is defined by a UV lamp, only schematically indicated, which is supported by wall 71 so as to irradiate the facing gripping member 19 and the relative opening device 2 during the movement of conveyor wheel 10. Preferably, the lamp defining radiating source 72 is an intermittent LED device synchronized with the movement of conveyor wheel 10.

Preferably, treatment device 74 comprises a light filter 75 which is interposed between image acquisition device 73 and the irradiated area of path P₃ and is adapted to stop electromagnetic radiations having wavelengths below a predetermined value V₀ correlated to the material and the coloring pigment of the portion of opening device 2 where layer 45 of adhesive is deposited.

In the example shown, opening device 2 is essentially made of polyethylene (about 98%) and includes a coloring pigment (about 2%) which is in turn essentially constituted by titanium dioxide (about 50%) and polyethylene (about 50%).

In this specific case, the electromagnetic radiations emitted by radiating source 72 have wavelengths distributed around 395 nm, preferably between 350 nm and 440 nm, and the predetermined value V₀, below which electromagnetic radiations are stopped by light filter 75, is 435 nm.

The image displayed by image acquisition device 73 is shown in FIG. 7, which refers to the case of correct deposition of layer 45 of adhesive on the relative opening device 2.

Monitoring device 70 enables effective illumination of the portion of opening device 2 where layer 45 of adhesive is deposited, and the layer itself, with extremely high contrast. In this way, due to the different reactions of the adhesive and of the material of opening device 2 to the electromagnetic radiations emitted by radiating source 72 and due to the interposition of light filter 75 between the irradiated area and image acquisition device 73, layer 45 of adhesive is highlighted in the captured image with respect to the surface on which such layer is deposited. Even the smallest defects can therefore be detected.

As clearly visible in FIG. 7, when deposited correctly, layer 45 of adhesive is uninterrupted; differently, when deposited incorrectly, it is interrupted circumferentially or has a radial thickness below a predetermined threshold value S.

The signal generated by image acquisition device 73 may be used to trigger:
rejection of opening devices 2 with incorrectly deposited adhesive;
an alarm; and/or
a unit stop.

The stored data may also be analyzed for compiling statistics and/or process control.

Operation of unit 1, which is already partly obvious from the foregoing description, will now be described with reference to one opening device 2, and as of the instant in which opening device 2, already coated with the layer of adhesive, travels through pickup station 11.

The gripping member 19 to receive opening device 2 is set to the best pickup position by cam follower rollers 29, 30 interacting with respective cams 27, 28, and is also set by cam 27 to the desired radial position, with respect to axis A, corresponding to a specific peripheral speed. The peripheral speed of gripping members 19 at pickup station 11 is preferably greater than the travelling speed of opening devices 2, so as to minimize impact between gripping members 19 and opening devices 2.

On reaching pickup station 11, gripping member 19 is moved towards path P₁ of opening devices 2 into the second forward operating position by its own cam follower roller 48 interacting with relative cam 50, and jaws 58, 59 are rotated into the open position by cam follower roller 65 of lever 64 interacting with relative cam 66.

Next, jaws 58, 59 of gripping member 19 are closed about relative opening device 2, and gripping member 19 is withdrawn from path P₁ back into the first withdrawn operating position.

The position and travelling speed of gripping member 19 along path P₃ are determined by cam follower rollers 28, 29 interacting with cams 27, 28, and, along path P₃, the spacing of opening devices 2 is made equal to spacing D₂ of packages 3.

When gripping member 19 and the relative opening device are in front of monitoring apparatus 70, radiating source 72 is activated so as to irradiate both.

At this point, image acquisition device 73 captures the image of the irradiate area through the filtering action performed by light filter 75, which prevents wavelength below value V₀ to reach image acquisition device 73. The result of the filtering action is represented in FIG. 7.

Image acquisition device 73 displays the shape of layer 45 and generates a signal associated to that shape.

If the radial thickness of layer 45 is constantly above value S, gripping member 19 continues its movement along paths P₃ and P₂.

Close to application station 12, cam follower roller 48 of gripping member 19 interacts with relative cam 50 to move gripping member 19 back into the second forward operating position; and, at the same time, cam follower roller 65 of lever 64 interacts with relative cam 66 to rotate jaws 58, 59 into the open position to release opening device 2 once it is deposited on respective package 3.

If the radial thickness of layer 45 is below value S in certain points, the signal generated by image acquisition device 73 may trigger a unit stop, rejection of the opening device 2 with incorrectly deposited adhesive or an alarm.

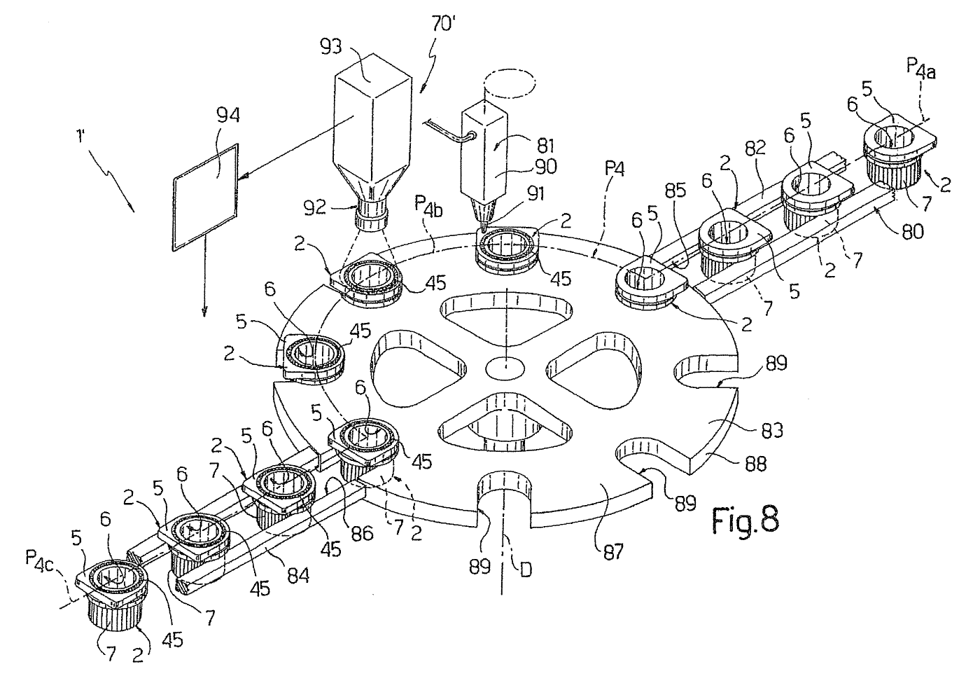

Number 1′ in FIG. 8 indicates as a whole a different embodiment of a unit, in accordance with the teachings of the present invention, for preparing a succession of closable plastic opening devices 2 for gluing to the respective packages 3; unit 1′ is described below only insofar as it differs from unit 1, and using the same reference numbers for component parts corresponding or equivalent to those already described.

Unit 1′ substantially comprises a conveyor 80 for conveying opening devices 2 successively along a path P₄ from a packaging machine station (not shown) located upstream from unit 1′, to a known application station (not shown) located downstream from unit 1′ and where each opening device 2 is applied to a respective package 3; and a dispenser 81 for depositing a layer 45 (shown in FIGS. 8, 9, 11) of adhesive—in the example shown, high-temperature liquid glue—onto a portion of frame 5, of each opening device 2, to be applied to a corresponding package 3.

More specifically, as it travels along path P₄, each opening device 2 interacts with dispenser 81, and layer 45 of adhesive is deposited on the relative portion of frame 5.

Also in this case, when cap 7 is provided with an internal portion designed to be directly attached to the removable portion of package 3, the layer of adhesive may be also distributed on that portion of the cap.

Path P₄ comprises, in orderly succession:
a straight first portion P₄ₐ, along which opening devices 2 are picked up from the station upstream from unit 1′ and fed to dispenser 81;
an arc-shaped second portion P_{4b}—in the example shown, extending along a hundred-and-eighty-degree arc—along which opening devices 2 interact with dispenser 81;
a straight third portion P_{4c}, along which opening devices 2, with layer 45 of liquid glue, are conveyed to the application station.

More specifically, portions P₄ₐ, P_{4b}, P_{4c} are coplanar, so that path P₄ lies in one plane positioned horizontally in use.

Conveyor 80 substantially comprises a guide 82 (only shown partly in FIG. 8) extending longitudinally and for moving opening devices 2 along portion P₄ₐ; a circular guide 83 for moving opening devices 2 along portion P_{4b}; and a guide 84 (only shown partly in FIG. 8) extending longitudinally on the opposite side of guide 83 to guide 82, and for moving opening devices 2 along portion P_{4c}.

Each opening device 2 is conveyed by guides 82, 83 and 84 with the adhesive-receiving portion of opening device 2 facing upwards, on the same side as dispenser 81, and with cap 7 facing downwards, on the opposite side of the above-mentioned portion to dispenser 81.

More specifically, guides 82 and 84 are located on diametrically opposite sides of guide 83, and extend in parallel directions.

Guides 82 and 84 are each driven by a respective motor not shown, and cooperate with opening devices 2 on opposite sides of respective path portions P₄ₐ, P_{4c} to define respective seats 85, 86 for housing opening devices 2 as they are fed to and from guide 83 respectively.

Guide 83 comprises a flange 87 rotated about a vertical axis D perpendicular to the plane of path P₄. More specifically, along an outer circumferential end edge 88 with respect to axis D, flange 87 has a number of—in the example shown, eight—seats 89 complementary in shape to opening devices 2, and for guiding opening devices 2 along portion P_{4b}.

Seats 89 are formed through flange 87, and, on the opposite side to axis D, are open to receive opening devices 2 from guide 82 and feed them along portion P_{4b} to guide 84.

The rotation direction of guide 83 about axis D is such that each seat 89 is positioned cyclically in:
a first angular position, in which it faces seat 85 to receive a given opening device 2 from guide 82;
a second angular position, in which adhesive-receiving portion of said opening device 2 is positioned vertically facing dispenser 81 to deposit layer 45; and
a third angular position, in which it faces seat 86 to feed opening device 2 to guide 84.

Dispenser 81 comprises a supporting body 90 connected to a liquid glue tank; and a nozzle 91 projecting from body 90 and for depositing adhesive onto each opening device 2.

More specifically, dispenser 81 is located over guide 83 and eccentrically with respect to axis D, so that nozzle 91 is located over adhesive-receiving portion of opening device 2 housed inside seat 89 in the second angular position.

Dispenser 81 rotates about an axis parallel to axis D to allow nozzle 91 to deposit an annular layer 45 onto a relative portion of each opening device 2.

Unit 1′ advantageously comprises a monitoring apparatus 70′ based on a sensor 92, which is sensitive to the difference in temperature between adhesive layer 45 and adhesive-receiving portion of opening device 2, and which generates a signal associated with the shape of layer 45.

More specifically, sensor 92 is sensitive to the difference in the infrared waves emitted by layer 45 and adhesive-receiving portion of opening device 2 because of their difference in temperature.

The difference in temperature is considerable, in that the adhesive is dispensed at roughly 200 degrees centigrade, whereas adhesive-receiving portion of opening device 2 is at ambient temperature.

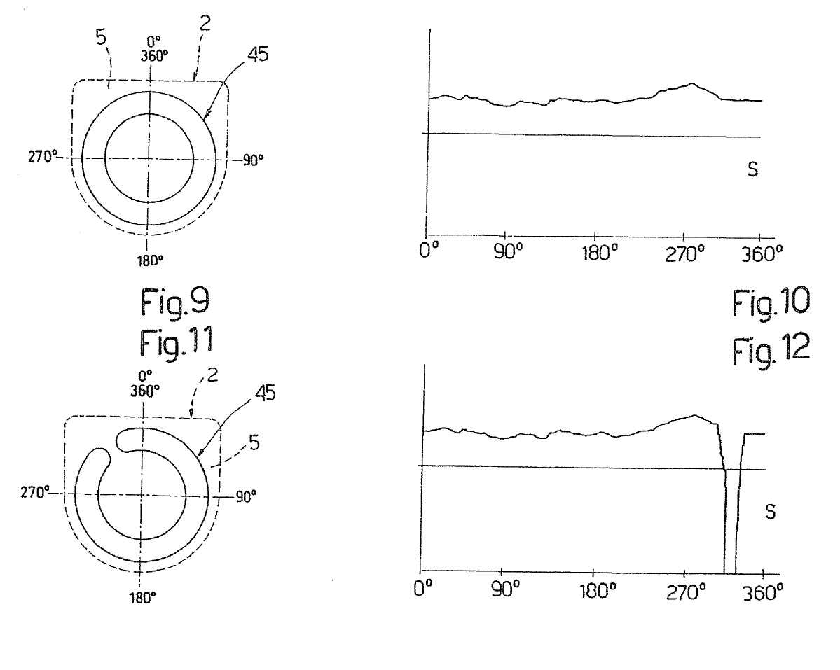

Sensor 92 is integrated in an infrared television camera 93, which processes the signal generated by sensor 92 to display the shape of layer 45 (FIGS. 9, 11).

Television camera 93 is located eccentrically with respect to axis D, and interacts with each opening device 2 after layer 45 has been deposited and while respective seat 89 is in an intermediate position between the second and third angular position.

The images displayed by television camera 93 are shown in FIGS. 9 and 11, which indicate correct and incorrect deposition of layer 45 respectively.

When deposited correctly (FIG. 9), layer 45 is uninterrupted, whereas, when deposited incorrectly (FIG. 11), it is interrupted circumferentially or has a radial thickness below a predetermined threshold value S.

Unit 1′ also comprises a data processing unit 94, which processes the image displayed by television camera 93 to extract the radial thickness pattern (FIGS. 10, 12) of layer 45 as a function of the angle between a fixed direction coplanar with layer 45, and a radial direction joining the centre of layer 45 to a thickness measuring point.

FIG. 10 shows the radial thickness pattern of layer 45 when the adhesive is deposited correctly.

In which case, layer 45 is of uninterrupted annular shape (FIG. 9), and has a radial thickness above predetermined value S for any value of the angle between a fixed direction coplanar with layer 45, and the radial direction joining the centre of layer 45 to a layer 45 thickness measuring point.

FIG. 12 shows the radial thickness pattern of layer 45 when deposited incorrectly.

In which case, layer 45 is interrupted circumferentially (FIG. 11), and has a radial thickness below value S at certain values of the angle between a fixed direction on opening device 2, and the direction joining the centre of layer 45 to a layer 45 thickness measuring point.

Unit 94 is interfaced with a control unit, which stops unit 1′ when the radial thickness of layer 45 is below value S.

In actual use, conveyor 80 feeds opening devices 2 along path P₄ to supply the application station with opening devices 2 with layer 45 of liquid glue deposited correctly thereon.

Opening devices 2 travel along path P₄ with the adhesive-receiving portion facing dispenser 81, and with cap 7 facing the opposite way.

More specifically, guide 82 first feeds each opening device 2, inside seat 85, along straight path portion P₄ₐ.

Each opening device 2 is then picked up by a respective seat 89 in flange 87 and fed, by flange 87 rotating about axis D, along a hundred-and-eighty-degree arc along path portion P_{4b}.

More specifically, each seat 89 receives respective opening device 2 from guide 82 in the first angular position of seat 89, and moves it into the second angular position of seat 89, in which the relative adhesive-receiving portion is positioned facing nozzle 91 of dispenser 81.

In the second angular position, nozzle 91 deposits layer 45 of liquid glue onto the adhesive-receiving portion of said opening device 2.

Once layer 45 is deposited, each seat 89 is moved by flange 87 into an intermediate position between the second and third angular position, so that adhesive-receiving portion of respective opening device 2 is positioned facing sensor 92 integrated in television camera 93.

At this point, sensor 92 determines the quantity of infrared waves emitted by layer 45 and by the area of adhesive-receiving portion surrounding layer 45, and transmits the findings to television camera 93.

The liquid glue being at a higher temperature (roughly 200 degrees centigrade) than adhesive-receiving portion of opening device 2, layer 45 emits more infrared waves than the area of such portion surrounding layer 45.

Television camera 93 displays the shape of layer 45 (FIGS. 9, 11), and unit 94 processes the display to determine the radial thickness pattern of layer 45 (FIGS. 10, 12) as a function of the angle between a fixed direction integral with opening device 2, and a direction varying in space.

If the radial thickness of layer 45 is constantly above value S for each value of the above angle, seat 89 feeds respective opening device 2 into the third angular position of seat 89, in which respective opening device is positioned facing seat 86 of guide 84, and can be picked up by guide 84 for supply to the application station.

If the radial thickness of layer 45 is below value S for one or more values of the above angle, the control unit stops the machine to prevent opening device 2 from being supplied to the application station.

The advantages of units 1, 1′ and the method according to the present invention will be clear from the foregoing description.

In particular, units 1, 1′ permit repeatable, easy, automatic control of the shape of layer 45 of adhesive deposited on adhesive-receiving portion of each opening device 2.

This therefore safeguards, in the event of incorrect deposition of layer 45, against in-use detachment of opening devices 2 from the respective packages 3, and in-use leakage of the pourable food product between each opening device 2 and the relative package 3.

On the opposite point of view, this allows a reduction of operating costs as it is avoided application of excessive amounts of adhesive to prevent the above-mentioned in-use inconveniences.

Using monitoring apparatus 70, detection of the shape of layer 45 of adhesive on the relative opening device 2 can be performed at any distance from the station (51) where adhesive is deposited, before application station 12.

Using monitoring apparatus 70′, detection of the shape of layer 45 is to be performed close to the station (81) where adhesive is deposited, otherwise the difference in temperature between layer 45 and the adhesive-receiving portion of the relative opening device 2, decreases. However, monitoring apparatus 70′ permits to control the shape of layer 45 regardless of ambient light conditions and the colour contrast conditions of layer 45 and adhesive-receiving portion of the relative opening device 2.

Clearly, changes may be made to units 1, 1′ and the method as described herein without, however, departing from the protective scope as defined in the accompanying Claims.

1. A unit for preparing an opening device for gluing to a respective sealed package of a pourable food product; said unit comprising:
conveying means for feeding said opening device (2) along a predetermined path;
dispensing means for depositing a layer of adhesive onto a portion of said opening device to be applied to a corresponding package; and
monitoring means for identifying, on said opening device, a position of said layer of adhesive with respect to the portion on which the adhesive is deposited, and which generate a signal associated with a shape of the identified layer.

2. A unit as claimed in claim 1, wherein said monitoring means comprises:
radiating means which are selectively activated for irradiating a given area of said path traveled across by said opening device and which emit electromagnetic radiations having given wavelengths at least in part in the ultraviolet region;
image acquisition means for capturing the image of the irradiated area and generating said signal associated with the detected shape of said layer (45) of adhesive; and
treatment means for creating sufficient contrast in the captured image between said layer of adhesive and the portion of the opening device where said layer is deposited.

3. A unit as claimed in claim 2, wherein said treatment means comprise a light filter which is interposed between said image acquisition means and the irradiated area of said path and is adapted to stop electromagnetic radiations having wavelengths below a predetermined value correlated to the material and a coloring pigment of the portion of said opening device which receives the adhesive.

4. A unit as claimed in claim 3, wherein said predetermined value, below which electromagnetic radiations are stopped by said light filter, is in the visible region.

5. A unit as claimed in claim 3, wherein the electromagnetic radiations emitted by said radiating means have wavelengths distributed around 395 nm, and wherein said predetermined value, below which electromagnetic radiations are stopped by said light filter, is 435 nm.

6. A unit as claimed in claim 1, wherein said radiating means comprise an intermittent LED device synchronized with the movement of said conveying means.

7. A unit as claimed in claim 1, wherein said monitoring means comprise sensor means, which are sensitive to the difference in temperature between said layer of adhesive and said portion of said opening device on which the adhesive is deposited.

8. A unit as claimed in claim 7, wherein said signal is displayable.

9. A unit as claimed in claim 7, wherein said sensor means are sensitive to the quantity of infrared waves emitted by said layer of adhesive and by said portion of said opening device on which the adhesive is deposited.

10. A unit as claimed in claim 8, wherein said displayable signal is supplied to a television camera.

11. A unit as claimed in claim 1, wherein said layer is annular in shape, and wherein said signal is associated with radial thickness of said layer.

12. A method of preparing an opening device for gluing to a respective package of a pourable food product; said method comprising:
feeding said opening device along a predetermined path;
depositing a layer of adhesive onto a portion of said opening device to be glued to a corresponding package;
identifying, on said opening device, a position of said layer of adhesive with respect to the portion on which the adhesive is deposited; and
generating a signal associated with the shape of the identified layer.

13. A method as claimed in claim 12, wherein said step of identifying comprises:
irradiating a given area of said path traveled across by said opening device with electromagnetic radiations having given wavelengths at least in part in the ultraviolet region;
capturing the image of the irradiated area; and
creating sufficient contrast in the captured image between said layer of adhesive and the portion of the opening device where said layer is deposited.

14. A method as claimed in claim 13, wherein said step of creating sufficient contrast in the captured image is performed through a light filter which stops electromagnetic radiations having wavelengths below a predetermined value correlated to the material and the coloring pigment of the adhesive-receiving portion of said opening device.

15. A method as claimed in claim 14, wherein said predetermined value, below which electromagnetic radiations are stopped by said light filter, is in the visible region.

16. A method as claimed in claim 12, wherein said step of identifying comprises the step of determining the difference in temperature between said layer of adhesive and the portion of said opening device receiving the adhesive.

17. A method as claimed in claim 16, wherein said step of generating a signal comprises the step of generating a displayable signal.

18. A method as claimed in claim 16, wherein said determining step comprises determining the quantity of infrared waves emitted by said layer of adhesive and by the portion of said opening device receiving the adhesive.

19. A method as claimed in claim 16, wherein it further comprises supplying said displayable signal to a television camera.

20. A method as claimed in claim 12, wherein said layer of adhesive is deposited as an annular layer of adhesive, and the generated said signal is associated with radial thickness of said layer.
